(19) United States
(12) Patent Application Publication
(10) Pub. No.: US 2026/0182472 A1
(43) Pub. Date: Jun. 25, 2026

(54) ELECTRICAL CONDUCTOR DEVICE AND METHOD FOR MANUFACTURING AN ELECTRICAL CONDUCTOR DEVICE

(71) Applicant: Robert Bosch GmbH, Stuttgart (DE)

(72) Inventors: Armin Himmelstoss, Weissach Im Tal (DE); Maik Hansen, Leonberg (DE)

(21) Appl. No.: 19/128,815

(22) PCT Filed: Jan. 16, 2024
(86) PCT No.: PCT/EP2024/050847

§ 371 Date: May 9, 2025

(30) Foreign Application Priority Data
Feb. 15, 2023 (DE) 10 2023 201 263.4

(51) Int. Cl. H10W 90/00; H10W 72/20; H10W 72/90

(52) U.S. Cl. CPC H10W 90/724; H10W 72/20; H10W 72/9415; H10W 90/701; H10W 90/734

(57) ABSTRACT

An electrical conductor device. The electrical conductor device includes a conductor unit having a top side and an array of conductor contacts on the top side. The array corresponds to a predetermined pattern and forms a contact path area along a region of the predetermined pattern. The electrical conductor further includes an electronic component, with soldering points and solder material on a bottom side of the electronic component. The soldering points with the solder material can be placed on the conductor contacts. The soldering points with the solder material placed on the conductor contacts form a contact point running along the contact path area.

### FIELD

The present invention relates to an electrical conductor device and a method for manufacturing an electrical conductor device.

### BACKGROUND INFORMATION

Currently, for high-frequency chips, ball grid arrays (BGA) or land grid arrays (LGA) may be utilized as packages, wherein a BGA package is typically utilized for very large chips and LGA packages may be utilized in smaller first-level packages for automotive applications. However, an industrial use may also be carried out with larger packages.

In this respect, it must be considered that different expansion coefficients of the packages relative to the conductor device (circuit board) may be possible in an operating temperature range.

Typically, for transmission of a high frequency, a galvanic attachment with shielding/shield ring (on the conductor device) and an electromagnetic attachment may be utilized with high frequency antennas (launchers) on/in the first level package.

European Patent No. EP 1 722 614 B1 describes a printed circuit board and a method for its manufacture.

### SUMMARY

The present invention provides an electrical conductor device and a method for manufacturing an electrical conductor device.

Preferred developments of the present invention are disclosed herein.

The present invention provides an electrical conductor device and a method for manufacturing an electrical conductor device, wherein shielding properties of contact areas (for example at interfaces and/or transitions) may be improved.

According to an example embodiment of the present invention, the electrical conductor device includes a conductor unit having a top side and an array of conductor contacts on the top side, wherein the array corresponds to a predetermined pattern and forms a contact path area along a region of the predetermined pattern; an electronic component, with soldering points and solder material on a bottom side of the electronic component, wherein the soldering points with the solder material can be set upon the conductor contacts, wherein the soldering points with the solder material set upon the conductor contacts form a contact point running along the contact path area.

A so-called first-level package with an improved electromagnetic (EM/EMC) shielding property and improved EM wave transport properties may advantageously be achieved.

For example, integrated circuits, such as high frequency ICs, may be used as electronic components, for example for radio technology, communication, sensing, radar, or other purposes.

According to an example embodiment of the present invention, it may be achieved that even for higher frequencies (with a shorter wavelength), the contact point surrounding the high frequency transport path (this may comprise one or multiple sub-areas) may represent a shield, advantageously a shield that is as homogeneous as possible and closed or impervious as possible.

Thus, it is possible to reduce or avoid an influence according to commonly present distances in the ball soldering point array and the height between the components and the resulting apertures, where high-frequency radiation may then escape or be radiated in in the usual manner.

An occurrence of undesired couplings between adjacent high frequency transmission channels in a package may then be reduced or avoided.

Furthermore, a typically occurring transport loss may be reduced, which may usually arise at higher frequencies, because in this case the (ball) contacts surrounding the high frequency transport path (mostly to ground potential) no longer represent a homogeneous waveguide, which may, however, be reduced by the continuous contact area from the present invention.

Since apertures usually occur in the case of spaced contacts, given by the distance between the contacts and the height between the components (between the conductor device and the electronic device, which may be referred to as “stand-offs”) and, due to this, the electromagnetic wave may no longer propagate homogeneously, this may lead to increased transport losses.

According to an example embodiment of the present invention, it may be advantageously achieved that an effect and occurrence of such inhomogeneities may be eliminated or reduced, which may lead to improved shielding and transmission behavior in ball grid arrays.

The conductor unit may comprise a circuit board or circuit card, and the electronic component may comprise a chip, an encapsulation with an interposer, and the soldering points and solder material on a bottom side of the electronic component. The interposer may be a distribution plane (usually also a circuit card, which is cast into the chip housing). Using the interposer, a chip/semiconductor contact surface may be wired onto the larger BGA/LGA layout (ball or land grid array).

According to an example embodiment of the present invention, the electronic component may comprise the chip in the center or in a central region of the encapsulation and/or of the interposer, wherein the area with the soldering points on the bottom side of the interposer may extend beyond the area of the chip or may be disposed only outside the chip area.

The conductor contacts may comprise coaxial lines and/or microstrip lines, which may run on and/or through the conductor unit.

Typically, no closed or semi-open soldering (ring) profiles are realized beyond a contact area, such as a ball contact; for example, a U-shape is unusual. According to the present invention, this limitation may be eliminated for contact points, advantageously for ball contact arrays. Radiation into adjacent components from the electronic component, as well as a radiation coupling, may be reduced or avoided, as a shielding effect may be improved. Shielding and HF transport properties may also be significantly improved.

With regard to the soldering points and the solder material, for example the balls in a ball grid array, a certain distance between the soldering points (for example the balls) and a thickness of these soldering points (for example the balls) may be provided. The contiguous contact path area and the contact point running through it may represent improved shielding, and undesirable couplings to adjacent HF connections on the package may be reduced.

According to a preferred embodiment of the electrical conductor device of the present invention, the conductor unit comprises a circuit card or a circuit board.

The circuit board may be a printed circuit board (PCB).

According to a preferred embodiment of the electrical conductor device of the present invention, the conductor contacts represent a ball grid array.

The ball grid array may have predetermined distances, wherein these may relate to both the conductor contacts as land contacts on the conductor unit and to the soldering points as counter contacts on the electronic component, wherein these counter contacts may then represent so-called ball contacts with the solder material in ball form. The ball contacts and the conductor contacts may have a specific radius.

According to a preferred embodiment of the electrical conductor device of the present invention, the contact point consists of the solder material and forms a continuous contact wall between the top side of the conductor unit and the bottom side of the electronic component and comprises electromagnetic shielding properties.

According to a preferred embodiment of the electrical conductor device of the present invention, the predetermined pattern is a grid array and the area of the predetermined pattern forms a fully enclosed or open rectangle for the contact path area.

For example, the contact path area may have a U-shape and may surround the soldering points of the electronic component laterally at least in regions.

According to a preferred embodiment of the electrical conductor device of the present invention, the area of the predetermined pattern for the contact path area forms an open rectangle and comprises an aperture to a specific side of the conductor unit, wherein the conductor unit comprises a waveguide, which extends through the aperture to the open rectangle or into it.

Due to the contact path area, an improved shielding effect may be achieved on its closed side, although this will, in contrast, be reduced to the open side and radiation may be oriented into/out of this direction, which may be utilized by an existing waveguide to improve the waveguide transmission there.

According to a preferred embodiment of the electrical conductor device of the present invention, the conductor contacts for the contact path area have a smaller surface area compared to the conductor contacts outside the contact path area.

If all soldering points have an equal amount and dimension of solder material, then, upon placing the soldering points onto the land contacts/conductor contacts, a formation of the contact point running along the contact path area may be achieved, so that less solder material is required per soldering point to generate the contact there than may be compensated for at the remaining contact locations outside the contact path area, and thus the path area between the separated or connected conductor contacts and soldering points in the contact path area over the area with solder material.

The ball grid housing of the encapsulation of the electronic component with an internal chip may advantageously be provided with solder balls. The size of these balls may be varied according to a required amount of solder.

Prior to soldering with the components, the circuit board may be wetted with solder and flux only at the locations to be soldered, wherein such selective wetting may be prepared by placing a hole template on the circuit card (the thickness of the template affects the amount of solder). Then, by means of a doctor blade, a solder paste may be distributed over the template and then the template may be removed and the components (for example, the ball grid array with the electronic component/BGA) may be placed on the circuit card (with the coated soldering depot). Then the whole may be sent into a soldering furnace.

A height between the electronic component and the conductor unit may advantageously remain the same in all locations.

According to a preferred embodiment of the electrical conductor device of the present invention, the electronic component is configured to radiate and/or receive an electromagnetic radiation.

According to a preferred embodiment of the electrical conductor device of the present invention, a predetermined distance between the top side of the conductor unit and the bottom side of the electronic component is maintained.

As a whole, the electronic component may be provided with soldering points and the solder material also in the usual dimension and with the adjusted dimension of the conductor unit with the conductor contacts, a bridge connection to the nearest soldering point may also be created via standardized soldering processes. An impervious and/or closed metallically conductive plane or wall may be generated by the contact point running along the contact path area and a very good shielding of the HF-conducting path may be achieved. In this way, with a closed or partially open shape, for example a rectangle, a shield ring may be produced at least in regions laterally around the electronic component, which may be connected to a ground potential, for example. If an EM wave occurs, the damping and/or transport properties may be improved, wherein advantageously no special housing or special designs are needed in the package, although these are also possible.

Furthermore, geometries of the soldering points and/or the conductor contacts (land areas) on the conductor unit and/or the package itself may be adjusted to gaps and diameters of the soldering points. In this case, layout adjustments may be carried out on the conductor unit, including diameters of the ball contacts, if present, and thus allow for simple optimization of the bridge connection.

According to an example embodiment of the present invention, in the method for manufacturing an electrical conductor device, a conductor unit with a top side and an array of conductor contacts on the top side is provided, wherein the array corresponds to a predetermined pattern and forms a contact path area along a region of the predetermined pattern; and an electronic component is provided, with soldering points and solder material on a bottom side of the electronic component, wherein the soldering points with the solder material are placed on the conductor contacts, wherein a contact point running along the contact path area is formed with the soldering points with the solder material placed on the conductor contacts, which is advantageous in soldering.

According to a preferred embodiment of the method of the present invention, the contact point is formed from the solder material and a continuous contact wall is formed between the top side of the conductor unit and the bottom side of the electronic component.

According to a preferred embodiment of the method of the present invention, the region of the predetermined pattern for the contact path area is formed as a fully enclosed or open rectangle.

The electrical conductor device may also be characterized by the features mentioned in connection with the method and by the advantages of the method, and vice versa.

Further features and advantages of embodiments of the present invention arise from the following description with reference to the figures.

### BRIEF DESCRIPTION OF THE DRAWINGS

The present invention is explained in greater detail below with reference to the embodiment examples indicated in the schematic figures.

FIG. 1 shows a schematic illustration of a plan view of a top side of a conductor unit in an electrical conductor device according to an embodiment example of the present invention prior to placing an electronic component with soldering points.

FIG. 2 shows a schematic illustration of the conductor unit of FIG. 1.

FIG. 3 shows a schematic illustration of a plan view of a top side of a conductor unit in an electrical conductor device according to a further embodiment example of the present invention.

FIGS. 4A-4D schematically illustrate the conductor unit during placement of an electronic component according to an embodiment example of the present invention.

FIG. 5 shows a block diagram of method steps of the method for manufacturing an electrical conductor device according to an embodiment example of the present invention.

Identical reference signs in the figures denote identical or functionally identical elements.

### DETAILED DESCRIPTION OF EXAMPLE EMBODIMENTS

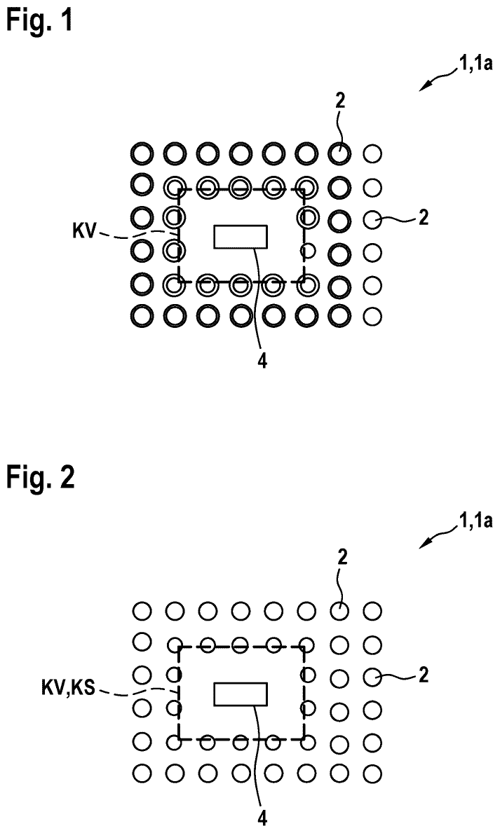

FIG. 1 shows a schematic illustration of a plan view of a top side of a conductor unit in an electrical conductor device according to an embodiment example of the present invention before placement of an electronic component with soldering points.

The plan view 1a of the conductor unit 1 is shown schematically with the pattern of the conductor contacts 2. Furthermore, after subsequent positioning (symbolically shown), the chip of the electronic component 4 is located in an area in the center above the conductor unit (only the chip is marked with the symbol “4” here).

An array of the conductor contacts 2 may correspond to a predetermined pattern, which in this case represents a grid. In an inner region of the grid array, there may be a contact path region KV present, which may advantageously form a rectangle. In this case, this contact path area KV is only shown as a trajectory, since a contact wall can only be present along this trajectory after the solder material of the soldering points has spread (not shown). In FIG. 1, in the right row of the conductor contacts 2, it is shown how their extension (dimension, radius) may look without the material of the soldering points, wherein the remaining conductor contacts 2 shown also show an overlay with the material of the soldering points, in particular in the relative size comparison with one another. The soldering points and the conductor contacts may advantageously be a ball grid array.

The double circles represent a schematic illustration of the conductor contacts 2 with the soldering points of the electronic component set on top. To make it possible to see the size dimensions, a conductor contact 2 is symbolically shown in the right region of the contact path area KV without the ball of the soldering point. The size dimensions of the double circle illustration may also be reversed; in this case, the conductor contact may comprise a larger radius than the soldering point.

However, the contact path area KV may also comprise metallic conductors or profiles, which may run between the conductor contacts 2 for the contact path area and may better receive or distribute the running solder material.

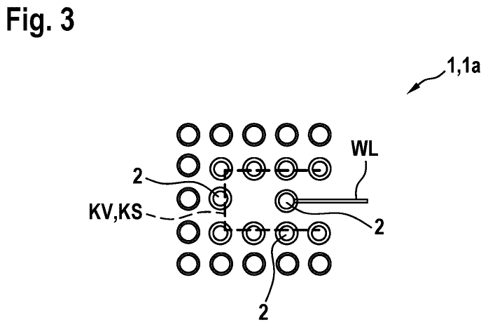

The electronic component 4 may comprise the chip in the center or in a center region of the encapsulation and/or the interposer, wherein the area with the soldering points may extend beyond the area of the chip on the bottom side of the interposer or, as shown in FIG. 1, may be disposed only outside the chip area (interposer and encapsulation are not shown). In FIG. 1, only the chip is marked as part of the electronic component 4 in order to provide a better overview; the areas of the encapsulation and/or the interposer with the soldering points over the conductor contacts 2 are also part of the electronic component 4, but are not shown in FIG. 1. FIGS. 2 and 3 also symbolically show the position of the chip as part of the electronic component 4 over the conductor unit 1.

FIG. 2 is a schematic illustration of the conductor unit of FIG. 1.

FIG. 2 shows how the array of conductor contacts 2 may be arranged. A surface area of those conductor contacts 2 in the contact path area KV may be less than outside the contact path area KV in order to be able to ensure sufficient solder material for forming the contact point KS.

FIG. 2 advantageously shows the conductor path structures on the conductor unit 1, which may be advantageously wetted with solder in the manufacturing process, wherein a hole mask and a doctor blade may be used.

FIG. 3 shows a schematic illustration of a plan view of a top side of a conductor unit in an electrical conductor device according to a further embodiment example of the present invention.

In FIG. 3, a similar array to the embodiment of FIG. 1 is shown, wherein, however, the contact path area KV forms a rectangle open to one side, in contrast to FIG. 1, in which the contact path area KV forms a closed rectangle. According to FIG. 3, a waveguide WL may further extend in or on the conductor unit 1 from one side into the rectangular area of the contact path area KV.

According to FIG. 3, for example, an RF signal may be conducted out of the package via the waveguide WL. The waveguide WL may be a coaxial waveguide and the contact point may represent a soldering ring for feeding the waveguide on a circuit card.

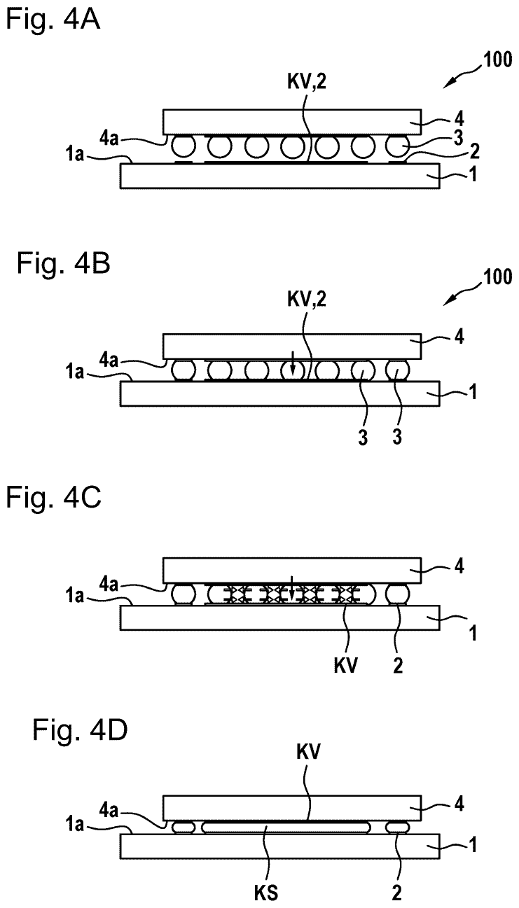

FIGS. 4A-4D each show a schematic illustration of the conductor unit during placement of an electronic component according to an embodiment example of the present invention.

In FIGS. 4A-4D, a sequence of the placement of the electronic component 4 on the conductor unit 1 is shown.

The conductor unit 1 comprises a top side 1a with an array of conductor contacts 2 on the top side 1a; according to FIG. 4A, this may be a ball grid array. Soldering points 3 may be formed on the bottom side 4a of the electronic component 4, for example as ball contacts, and placed (approximately) on the conductor contacts 2 and on the contact path area KV.

FIG. 4B shows how the soldering points 3 are placed on the conductor contacts 2 (KV) and a soldering of the contacts (FIG. 4C) begins.

According to FIG. 4C, it is shown how with a further approach and soldering of the soldering points to the conductor unit 1, the solder material may run along the contact path area KV. This may be achieved by the remaining material of the soldering points as solder contacts, which results from the smaller conductor contact surfaces. The solder may melt in a soldering furnace and run according to the illustration in FIG. 4D.

The contact point KS consists of the solder material and forms a continuous contact wall between the top side 1a of the conductor unit 1 and the bottom side 4a of the electronic component 4, which is shown in FIG. 4D.

According to FIG. 4D, it is also shown that the contact path area KV may also be located on the bottom side of the electronic component 4. Thus, the contact path area KV may be disposed on the electronic component and/or on the conductor unit and only comprise the soldering points/conductor contacts and/or also connecting lines between the adjacent soldering points/conductor contacts.

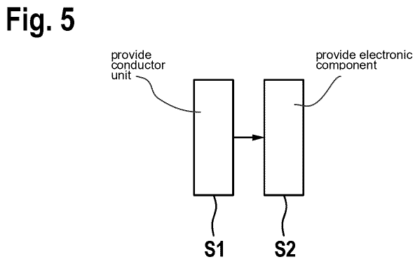

FIG. 5 shows a block diagram of method steps of the method for manufacturing an electrical conductor device according to an embodiment example of the present invention.

In the method of manufacturing an electrical conductor device, a conductor unit is provided S1 having a top side and an array of conductor contacts on the top side, wherein the array corresponds to a predetermined pattern and forms a contact path area along a region of the predetermined pattern; and an electronic component is provided S2 with soldering points and solder material on a bottom side of the electronic component, wherein the soldering points with the solder material are placed on the conductor contacts, wherein the soldering points with the solder material placed on the conductor contacts form a contact point running along the contact path area.

Although the present invention has been completely described above with reference to the preferred embodiment example, it is not limited thereto but may be modified in many ways.

1-12. (canceled)

13. An electrical conductor device, comprising,
a conductor unit having a top side, and an array of conductor contacts on the top side, wherein the array corresponds to a predetermined pattern and forms a contact path area along a region of the predetermined pattern;
an electronic component, with soldering points and solder material on a bottom side of the electronic component, wherein the soldering points with the solder material can be placed on the conductor contacts, wherein the solder joints with the solder material placed on the conductor contacts form a contact point running along the contact path area.

14. The electrical conductor device according to claim 13, wherein the conductor unit includes a circuit card or a circuit board.

15. The electrical conductor device according to claim 13, wherein the conductor contacts represent a ball grid array.

16. The electrical conductor device according to claim 13, wherein the contact point includes the solder material and forms a continuous contact wall between the top side of the conductor unit and the bottom side of the electronic component and includes electromagnetic shielding properties.

17. The electrical conductor device according to claim 13, wherein the predetermined pattern is a grid array and the region of the predetermined pattern for the contact path area forms a fully enclosed or open rectangle.

18. The electrical conductor device according to claim 17, wherein the region of the predetermined pattern for the contact path area forms an open rectangle and includes an opening to a specific side of the conductor unit, wherein the conductor unit includes a waveguide, which extends through the opening to the open rectangle or into it.

19. The electrical conductor device according to claim 13, wherein the conductor contacts for the contact path area have a smaller surface area than the conductor contacts outside the contact path area.

20. The electrical conductor device according to claim 13, wherein the electronic component is configured to radiate and/or receive electromagnetic radiation.

21. The electrical conductor device according to claim 13, wherein a predetermined distance between the top side of the conductor unit and the bottom side of the electronic component is maintained.

22. A method of manufacturing an electrical conductor device, the method comprising the following steps:
providing a conductor unit having a top side, and an array of conductor contacts on the top side, wherein the array corresponds to a predetermined pattern and forms a contact path area along a region of the predetermined pattern; and
providing an electronic component, with soldering points and solder material on a bottom side of the electronic component, wherein the soldering points with the solder material are placed on the conductor contacts, wherein the soldering points with the solder material placed on the conductor contacts form a contact point running along the contact path area.

23. The method according to claim 22, wherein the contact point is formed from the solder material and a continuous contact wall is formed between the top side of the conductor unit and the bottom side of the electronic component.

24. The method according to claim 22, wherein the region of the predetermined pattern for the contact path area is formed as a fully enclosed or open rectangle.
